(19) United States
(12) Patent Application Publication
(10) Pub. No.: US 2018/0026232 A1
(43) Pub. Date: Jan. 25, 2018

(54) THIN-FILM PACKAGE FOR ORGANIC LIGHT-EMITTING DIODE, ORGANIC LIGHT-EMITTING DIODE, AND ORGANIC LIGHT-EMITTING DISPLAY

(71) Applicant: EverDisplay Optronics (Shanghai) Limited, Shanghai (CN)

(72) Inventor: Ling XIAO, Shanghai (CN)

(73) Assignee: EverDisplay Optronics (Shanghai) Limited, Shanghai (CN)

(21) Appl. No.: 15/455,287

(22) Filed: Mar. 10, 2017

(30) Foreign Application Priority Data
Jul. 22, 2016 (CN) 201610584780.8

(51) Int. Cl. H01L 51/52

(52) U.S. Cl. CPC H01L 51/5256; H01L 2251/303; H01L 2251/301; H01L 2251/558; H01L 2251/5338

(57) ABSTRACT

The present invention relates to a thin-film package for an organic light-emitting diode, an organic light-emitting diode using the thin-film package, and an organic light-emitting display. The thin-film package includes at least one inorganic film layer and at least one organic film layer, the inorganic film layer and the organic film layer being alternately stacked; the inorganic film layer is made of a material selected from any one of poly(silicon nitride), poly(silicon oxide), poly(silicon carbonitride), poly(silicon carbooxide), poly(silicon carbonitride) and poly(silicon carbonitrideoxide), or any combination thereof; and the organic film layer is made of a material selected from any one of acrolein-based polymer, silicon-based polymer and epoxy-based polymer, or any combination thereof. Compared with a traditional thin-film package structure, the thin-film package according to the present invention achieves a better water and oxygen resistant effect, suffers from a lower stress, and is thus suitable for use in a flexible OLED.

### CROSS-REFERENCE TO RELATED APPLICATIONS

The present application claims priority to Chinese Patent Application No. 201610584780.8, filed on Jul. 22, 2016, and the entire contents thereof are incorporated herein by reference.

### TECHNICAL FIELD

The present invention relates to the field of organic electroluminescence, and in particular, relates to a thin-film package for an organic light-emitting diode, an organic light-emitting diode using the thin-film package, and an organic light-emitting display.

### BACKGROUND

An organic light-emitting diode (OLED) is a device which is injected with charge carriers after being applied with a voltage, and the recombination of the charge carriers excites an organic material to emit light. The OLED has such advantages as self-illumination, high efficiency, quick response, wide view angle, and residence on a flexible substrate, and may be fabricated into a display or an illumination device, which gains concerns from the society.

The thin-film package of the organic light-emitting diode, especially the thin-film package of a flexible OLED, is long time a difficulty in this field.

### SUMMARY

In view of the above problem and/or other problems in the prior art, one aspect of the present invention provides a thin-film package for an organic light-emitting diode. The thin-film package includes: at least one inorganic film layer and at least one organic film layer, the inorganic film layer and the organic film layer being alternately stacked; wherein the inorganic film layer is made of a material selected from any one of poly(silicon nitride), poly(silicon oxide), poly(silicon oxynitride), poly(silicon carbonitride), poly (silicon carbooxide) and poly(silicon carbonitrideoxide), or any combination thereof; and the organic film layer is made of a material selected from any one of acrolein-based polymer, silicon-based polymer and epoxy-based polymer, or any combination thereof.

For example, the thin-film package has a structure of 2 to 100 layers of alternately stacked inorganic film layers and organic film layers, and the thin-film package has a total thickness of 50 nm to 50 μm; and the inorganic film layer has a thickness of 10 nm to 20 μm, and the organic film layer has a thickness of 50 nm to 30 μm.

For example, the thin-film package has a structure of 2 to 50 layers; and the inorganic film layers have a thickness of 10 nm to 20 μm, and the organic film layers have a thickness of 50 nm to 30 μm.

For example, the inorganic film layer is made of poly(silicon nitride).

For example, the inorganic film layer is formed by means of spin coating, spray coating, screen printing, ink-jet printing, thermal deposition or drop coating.

Another aspect of the present invention provides an organic light-emitting diode. The organic light-emitting diode includes: a substrate; a display element disposed on the substrate; and a thin-film package disposed on the substrate for packaging the display element; wherein: the thin-film package is the thin-film package as described above.

For example, in the thin-film package, a layer most proximal to the display element is the inorganic film layer.

For example, the substrate is a flexible substrate.

Still another aspect of the present invention provides an organic light-emitting display, which uses the organic light-emitting diode as described above.

The thin-film package for an organic light-emitting diode according to the present invention uses a structure of alternately stacked inorganic film layers and organic film layers, wherein the inorganic film layer is made of a material selected from any one of poly(silicon nitride), poly(silicon oxide), poly(silicon oxynitride) poly(silicon carbonitride), poly (silicon carbooxide) and poly(silicon carbonitrideoxide), or any combination thereof. Compared with a traditional thin-film package structure, the thin-film package according to the present invention achieves a better water and oxygen resistant effect, suffers from a lower stress, and is thus suitable for use in a flexible OLED.

### BRIEF DESCRIPTION OF THE DRAWINGS

FIG. 1 is a schematic section view of an organic light-emitting diode according to one embodiment of the present invention;

FIG. 2 is a schematic section view of a thin-film package according to one embodiment of the present invention;

FIG. 3 is a schematic section view of a thin-film package according to another embodiment of the present invention; and

FIG. 4 is a schematic section view of a thin-film package according to another embodiment of the present invention.

### DETAILED DESCRIPTION

Exemplary embodiments of the present invention are hereinafter described in detail with reference to accompany drawings. However, the exemplary embodiments may be implemented in a plurality of manners, and shall not be construed as being limited to the implementation described hereinafter. On the contrary, such exemplary embodiments more thoroughly and completely illustrate the present invention, and convey the concepts of the exemplary embodiments to persons skilled in the art. In the drawings, like reference numerals denote like or similar structures or elements. Therefore, detailed descriptions of these structures or elements are not given any further.

In addition, the described characteristics, structures, or features may be incorporated in one or more embodiments in any suitable manner. In the description hereinafter, more details are provided such that sufficient understanding of the embodiments of the present invention may be achieved. However, a person skilled in the art should note that, without one or more of the specific details, other methods, elements, materials and the like may also practice the technical solutions of the present invention. Under some circumstances, commonly known structures, materials or operations are not illustrated or described in detail to in case various aspects of the present invention become ambiguous.

The phrases “formed/disposed/arranged above . . . ” used in this description should be understood as direct contact and non-direct contact.

The drawings of the present application are merely for schematically illustrating relative position relationships and electrical connections of the parts. Exaggerate drawings are employed for illustrating thicknesses of the layers at some positions, for ease of understanding. The thicknesses of the layers in the drawings do not denote a proportion relationship between the actual thicknesses of the layers.

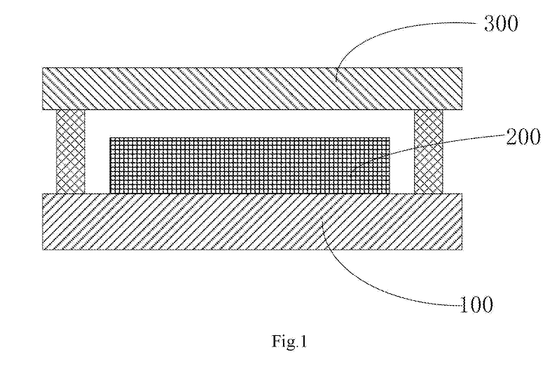

Referring to FIG. 1, a schematic section view of an organic light-emitting diode according to one embodiment of the present invention. The organic light-emitting diode includes: a substrate 100, a display element 200 and a thin-film package 300.

The substrate 100 may be a transparent insulating substrate. For example, the substrate 100 may be a flexible substrate, a glass substrate, a quartz substrate, a transparent plastic substrate or the like. For example, in this embodiment, the substrate 100 is a flexible substrate, which may employ a polyimide (PI) flexible substrate.

The display element 200 is arranged on the substrate 100. The display element 200 may be an OLED.

The thin-film package 300 is configured to bond to the substrate 100 to form a sealed space, such that the display element 200 is packaged in the sealed space.

In this embodiment, the organic light-emitting diode is a flexible OLED.

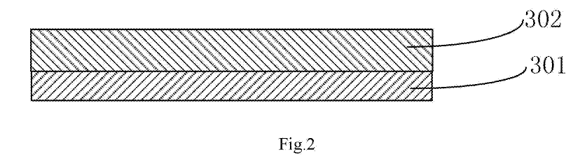

With respect to the thin-film package 300, reference may be made to FIG. 2. The thin-film package 300 includes at least one inorganic film layer 301 and at least one organic film layer 302, wherein the inorganic film layer 301 and the organic film layer 302 are alternately stacked.

The inorganic film layer 301 may be made of a material selected from any one of poly(silicon nitride), poly(silicon oxide), poly(silicon oxynitride), poly(silicon carbonitride), poly (silicon carbooxide) and poly(silicon carbonitrideoxide), or any combination thereof.

For example, in this embodiment, the inorganic film layer 301 is made of poly(silicon nitride).

The organic film layer 302 may be made of a material selected from any one of acrolein-based polymer, silicon-based polymer and epoxy-based polymer, or any combination thereof, for example, epoxy resin, acrylate, polyimide resin, silicon resin, polyethylene terephthalate (PET), polyimide (PI), polycarbonate (PC), polyethylene, polymethacrylate, polystyrene, polyester or the like.

For example, in this embodiment, the organic film layer 302 is made of acrylic resin.

The thin-film package 300 may have a structure of 2 to 100 layers of alternately stacked inorganic film layers 301 and organic film layers 302.

In this embodiment, the thin-film package 300 has a structure of two layers, wherein one is the inorganic film layer 301 and the other is the organic film layer 302.

The thin-film package 300 has a total thickness of 50 nm to 50 μm, the inorganic film layer 301 has a thickness of 10 nm to 20 μm, and the organic film layer 302 has a thickness of 50 nm to 30 μm.

For example, the thin-film package 300 has a total thickness of 500 nm to 20 μm, the inorganic film layer 301 has a thickness of 50 nm to 5 μm, and the organic film layer 302 has a thickness of 500 nm to 20 μm.

The inorganic film layer 301 may be formed by means of spin coating, spray coating, screen printing, ink-jet printing, thermal deposition or drop coating. In this embodiment, the inorganic film layer 301 is made of poly(silicon nitride) by means of spin coating.

The organic film layer 302 may be formed by means of thermal deposition, spin coating, spray coating, screen printing or ink-jet printing. In this embodiment, the organic film layer 302 is made of acrylic resin by means of spin coating.

In this embodiment, as illustrated in FIG. 2, in the thin-film package 300, a layer most proximal to the display element 200 is the inorganic film layer 301. To be specific, from the side proximal to the display element 200, the thin-film package 300 has a structure of firstly the inorganic film layer 301 and then the organic film layer 302 that are alternately stacked.

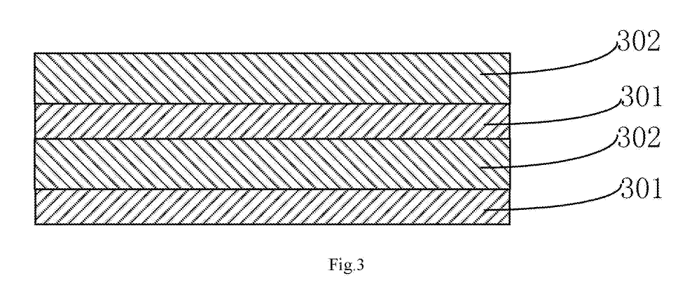

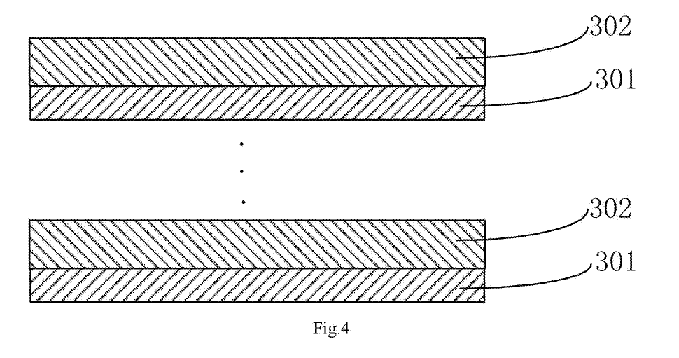

Referring to FIG. 4, in a specific embodiment of the present invention, the thin-film package 300 may have a multi-layer structure of the inorganic film layers 301 and the organic film layers 302 that are alternately stacked. For example, referring to FIG. 3, according to an embodiment of the present invention, the thin-film package 300 has a four-layer structure of the inorganic film layers 301 and the organic film layers 302 that are alternately stacked.

The thin-film package 300 according to the present invention uses a multiple-layer structure of alternately stacked inorganic film layers and organic film layers, wherein the inorganic film layer is made of a material selected from any one of poly(silicon nitride), poly(silicon oxide), poly(silicon oxynitride), poly(silicon carbonitride), poly (silicon carbooxide) and poly(silicon carbonitrideoxide), or any combination thereof. Compared with a traditional thin-film package structure, the thin-film package according to the present invention suffers from a lower stress, and is thus more suitable for use in a flexible OLED.

Nevertheless, the organic light-emitting diode using the thin-film package according to the present invention may be applied to an organic light-emitting display.

It should be understood that, although this specification is described based on the embodiments, not each of the embodiments discloses an independent technical solution. Such description manner of the specification is only for clarity. A person skilled in the art should consider the specification as an entirety. The technical solutions according to the embodiments may also be suitably combined to derive other embodiments that may be understood by a person skilled in the art.

A series of detailed descriptions given in this specifically are merely intended to illustrate feasible embodiments of the present invention, instead of limiting the protection scope of the present invention. Any equivalent embodiments or modification derived without departing from the spirit of the present invention shall fall within the protection scope of the present invention.

What is claimed is:

1. A thin-film package for an organic light-emitting diode, comprising at least one inorganic film layer and at least one organic film layer, the inorganic film layer and the organic film layer being alternately stacked; wherein:
the inorganic film layer is made of a material selected from any one of poly(silicon nitride), poly(silicon oxide), poly(silicon oxynitride), poly(silicon carbonitride), poly (silicon carbooxide) and poly(silicon carbonitrideoxide), or any combination thereof; and
the organic film layer is made of a material selected from any one of acrolein-based polymer, silicon-based polymer and epoxy-based polymer, or any combination thereof.

2. The thin-film package according to claim 1, wherein:
the thin-film package has a structure of 2 to 100 layers of alternately stacked inorganic film layers and organic film layers, and the thin-film package has a total thickness of 50 nm to 50 μm; and
the inorganic film layers have a thickness of 10 nm to 20 μm, and the organic film layers have a thickness of 50 nm to 30 μm.

3. The thin-film package according to claim 2, wherein:
the thin-film package has a structure of 2 to 50 layers; and
the inorganic film layers have a thickness of 10 nm to 20 μm, and the organic film layers have a thickness of 50 nm to 30 μm.

4. The thin-film package according to claim 1, wherein:
the inorganic film layer is made of poly(silicon nitride).

5. The thin-film package according to claim 2, wherein:
the inorganic film layer is made of poly(silicon nitride).

6. The thin-film package according to claim 1, wherein:
the inorganic film layer is formed by means of spin coating, spray coating, screen printing, ink-jet printing, thermal deposition or drop coating.

7. An organic light-emitting diode, comprising:
a substrate;
a display element disposed on the substrate; and
a thin-film package disposed on the substrate for packaging the display element; wherein:
the thin-film package is the thin-film package as defined in claim 1.

8. The organic light-emitting diode according to claim 7, wherein:
in the thin-film package, a layer most proximal to the display element is the inorganic film layer.

9. The organic light-emitting diode according to claim 7, wherein:
the substrate is a flexible substrate.

10. The organic light-emitting diode according to claim 7, wherein:
the thin-film package has a structure of 2 to 100 layers of alternately stacked inorganic film layers and organic film layers, and the thin-film package has a total thickness of 50 nm to 50 μm; and
the inorganic film layers have a thickness of 10 nm to 20 μm, and the organic film layers have a thickness of 50 nm to 30 μm.

11. The organic light-emitting diode according to claim 10, wherein:
the thin-film package has a structure of 2 to 50 layers; and
the inorganic film layers have a thickness of 10 nm to 20 μm, and the organic film layers have a thickness of 50 nm to 30 μm.

12. The organic light-emitting diode according to claim 7, wherein:
the inorganic film layer is made of poly(silicon nitride).

13. The organic light-emitting diode according to claim 7, wherein:
the inorganic film layer is formed by means of spin coating, spray coating, screen printing, ink-jet printing, thermal deposition or drop coating.

14. An organic light-emitting display using the organic light-emitting diode as defined in claim 7.

15. The organic light-emitting display according to claim 14, wherein:
the thin-film package has a structure of 2 to 100 layers of alternately stacked inorganic film layers and organic film layers, and the thin-film package has a total thickness of 50 nm to 50 μm; and
the inorganic film layers have a thickness of 10 nm to 20 μm, and the organic film layers have a thickness of 50 nm to 30 μm.

16. The organic light-emitting display according to claim 15, wherein:
the thin-film package has a structure of 2 to 50 layers; and
the inorganic film layers have a thickness of 10 nm to 20 μm, and the organic film layers have a thickness of 50 nm to 30 μm.

17. The organic light-emitting display according to claim 14, wherein:
the inorganic film layer is made of poly(silicon nitride).

18. The organic light-emitting display according to claim 14, wherein:
the inorganic film layer is formed by means of spin coating, spray coating, screen printing, ink-jet printing, thermal deposition or drop coating.

19. The organic light-emitting display according to claim 14, wherein:
in the thin-film package, a layer most proximal to the display element is the inorganic film layer.

20. The organic light-emitting display according to claim 14, wherein:
the substrate is a flexible substrate.
